(19) United States
(12) Patent Application Publication
(10) Pub. No.: US 2015/0153390 A1
(43) Pub. Date: Jun. 4, 2015

(54) MEASURING ELECTRONICS COMPRISING A CONTACT STRUCTURE

(71) Applicants: HELLA KGAA HUECK & CO., Lippstadt (DE); MILJØBIL GRENLAND AS, Porsgrunn (NO)

(72) Inventors: Ulrich Köhler, Lippstadt (DE); Alexej Greilich, Hamm (DE); Roman Stoiber, Porsgrunn (NO); Egil Engen, Langangen (NO); Sverre Wiik Øberg, Oslo (NO); Lars Ivarrud Brisendal, Brevik (NO)

(21) Appl. No.: 14/401,913

(22) PCT Filed: May 16, 2013
(86) PCT No.: PCT/EP2013/060141

§ 371 Date: Nov. 18, 2014

(30) Foreign Application Priority Data
May 18, 2012 (DE) 10 2012 208 381.2
May 25, 2012 (DE) 10 2012 208 854.7

(51) Int. Cl. G01R 1/067; G01R 31/36

(52) U.S. Cl. CPC G01R 1/06722; G01R 31/3644; G01R 1/06733

(57) ABSTRACT

The invention relates to a spring contact structure for contacting an electronic assembly and at least one contact element of an electric or electronic component, wherein the contact element is a projecting metallically conducting element and the electronic assembly has at least one resilient contact element which is supported by the contact element in an electrically conducting manner when force is applied to it. The invention also relates to a measuring device and a battery device.

### TECHNICAL FIELD

The invention relates to a spring contact-making structure for measuring electronics, to measuring electronics having a spring contact-making structure, and to a battery apparatus having measuring electronics and a spring contact-making structure.

### PRIOR ART

Battery apparatuses are known in the prior art. Battery apparatuses of this kind usually have a plurality of battery cells which are provided with in each case two electrical poles, a positive pole and a negative pole, and are arranged in the battery apparatus. The poles of the battery cells are generally connected in series in order to be able to use the plurality of battery cells, which each have only a low voltage between the poles, to generate a battery apparatus having a high operating voltage. Accordingly, a plurality of battery cells of this kind are arranged in a housing. In this case, battery apparatuses are known which have the cells arranged in a row, wherein the respective poles of adjacent battery cells have likewise arranged adjacent to one another. This is typically realized with battery cells which have a rather flat cuboidal shape or are produced in accordance with what is known as the “coffee bag” method.

Other battery apparatuses using round cells with a rather cylindrical shape exhibit a rather hexagonal arrangement of the battery cells.

When lithium-ion-type battery cells are used, but also in the case of other battery cells, the state of charge or the battery voltage of the individual cells is monitored during operation of the battery apparatus since excessive charging and, respectively, deep-discharging are intended to be avoided and reliable operation with a maximum service life is intended to be achieved.

To this end, the battery cells are nowadays connected to the measuring electronics by means of cables. To this end, the cables are either welded or connected by means of a cable shoe to the poles of the battery cells. The other end of the cable is then connected to a plug contact of the measuring electronics by means of a cable shoe.

The welded connection has the disadvantage that the process has to be carried out individually for each pole of the battery cell and furthermore is virtually impossible to release without destruction. The connection by means of a cable shoe can be released, but it is very complicated in respect of assembly and expensive in respect of connection to the cable.

### DESCRIPTION OF THE INVENTION, OBJECT, SOLUTION, ADVANTAGES

The object of the invention is to provide a spring contact-making structure for measuring electronics, measuring electronics having a spring contact-making structure, and a battery apparatus having measuring electronics and a spring contact-making structure, which spring contact-making structure allows contact to be made in a simple and reliable manner in comparison to the prior art.

The object in respect of the measuring apparatus is achieved by the features of claim 1, according to which a measuring apparatus having a spring contact-making structure for at least one contact element of an electrical or electronic unit to make contact with the measuring apparatus is provided, wherein the contact element is a protruding metallically conducting element, and the electronic assembly has at least one resilient contact-making element which is supported in an electrically conductive manner on the contact element when force is applied to it.

In this case, it is expedient when the apparatus comprises a circuit board, electronic elements being arranged on at least one face or both faces of said circuit board and electrical contact being made with said electronic elements, wherein resilient contact-making elements are arranged on at least one face or both faces of the circuit board and are electrically connected.

It is also advantageous when the apparatus comprises a circuit board on which the resilient contact-making elements are arranged in a manner distributed around the edge of the circuit board.

In this case, it is also advantageous when the resilient contact-making elements are arranged on the long longitudinal sides on one face of the circuit board.

It is further advantageous when the resilient contact-making elements are arranged on the short transverse sides on the opposite face of the circuit board.

It is expedient when resilient contact-making elements are arranged in groups.

In this case, it is advantageous when the contact-making elements which are arranged in one group are electrically conductively connected to one another.

It is further advantageous when the measuring apparatus is mounted in a floating and/or resilient manner by means of the resilient contact-making elements on the contact elements. Vibration damping can be performed in this case, it being possible for said vibration damping to protect the electronic components on the circuit board or on the measuring apparatus in this way.

It is also expedient when a test process of the measuring apparatus or of the circuit board of the measuring apparatus can be carried out in such a way that the measuring apparatus or, respectively, the circuit board can be clamped into a testing apparatus by means of the resilient contact-making elements and signals can be supplied to the circuit board or, respectively, measuring apparatus in order to test said circuit board or measuring apparatus.

The object in respect of the spring contact-making structure is achieved by the features of claim 10, according to which a spring contact-making structure for at least one contact element of an electrical or electronic unit to make contact with an electronic assembly is provided, wherein the contact element is a protruding metallically conductive element, and the electronic assembly has at least one resilient contact-making element which is supported in an electrically conductive manner on the contact element when force is applied to it.

It is advantageous when the electronic assembly has a plurality of contact-making elements for making contact with a plurality of contact elements of an electrical or electronic unit or a plurality of electrical or electronic units.

It is also expedient when the resilient contact-making element can be connected to the electronic assembly by way of at least one fastening region, and a part of the contact-making element, which part projects away from the fastening region, can be deformed in a resilient manner at least in one direction, and can be applied to the contact elements in such a way that resilient deformation takes place in the direction in which deformation is possible.

It is also expedient when the resilient contact-making element comprises a metallic strip which can be deformed in a resilient manner in the direction perpendicular to the narrowest extent of the strip.

It is advantageous when the resilient contact-making element is of C-, Z- or U-shaped design, wherein one region of the contact-making element is provided as a fastening region, it being possible for the contact-making element to be connected to the electronic assembly by means of said fastening region.

It is also advantageous when the resilient contact-making element is of arcuate design, and has fastening regions in a central region or in one or in both end regions, it being possible for the contact-making element to be connected to the electronic assembly by means of said fastening region.

It is expedient when the resilient contact-making element has a plurality of resilient tongues.

It is also advantageous when the resilient contact-making element is applied laterally to a contact element and is supported there.

It is further expedient when the resilient contact-making element engages between two contact elements and is applied to and supported on the two contact elements.

It is also advantageous when the electronic assembly is an electronic measuring apparatus, and the resilient contact-making elements are connected to a circuit board of the measuring device.

It is advantageous when the electrical or electronic unit is a battery apparatus having a battery cell or having a plurality of battery cells.

The object in respect of the battery apparatus is achieved by the features of claim 21, according to which a battery apparatus having at least one battery cell, preferably having a plurality of battery cells, having in each case two connection poles, which are in the form of contact elements, for each battery cell, and having a measuring apparatus with resilient contact-making means is provided, wherein the measuring apparatus makes electrical contact with at least individual contact elements by means of the resilient contact-making means.

To this end, it is advantageous when the contact elements of the battery cells are arranged in two spaced-apart rows, and the measuring apparatus is arranged substantially between and/or above the two rows.

It is also advantageous when the measuring apparatus has a circuit board with resilient contact-making elements which are directed downward or laterally to the outside and which make contact with contact elements of the battery cells.

It is advantageous when the measuring apparatus is arranged on the side of the contact elements of the battery apparatus and is covered by means of a cover.

Further advantageous refinements are described by the following description of figures and by the dependent claims.

### BRIEF DESCRIPTION OF THE DRAWINGS

The invention will be explained in greater detail below on the basis of at least one exemplary embodiment with reference to the drawings, in which:

FIG. 1 shows a perspective view of a top face of measuring electronics of a first exemplary embodiment of the invention,

FIG. 2 shows a perspective view of a bottom face of measuring electronics of a first exemplary embodiment of the invention,

FIG. 3 shows a view of a top face of measuring electronics of a first exemplary embodiment of the invention,

FIG. 4 shows a perspective view of a bottom face of measuring electronics of a first exemplary embodiment of the invention,

FIG. 5 shows a perspective view of a resilient contact-making element of one exemplary embodiment of the invention,

FIG. 6 shows a perspective view of a resilient contact-making element of one exemplary embodiment of the invention,

FIG. 7 shows a perspective view of a resilient contact-making element of one exemplary embodiment of the invention,

FIG. 8 shows a perspective view of a resilient contact-making element of one exemplary embodiment of the invention,

FIG. 9 shows a perspective view of a resilient contact-making element of one exemplary embodiment of the invention,

FIG. 10 shows a perspective view of a battery apparatus having measuring electronics,

FIG. 11 shows a perspective view of a battery apparatus having measuring electronics, and

FIG. 12 shows a perspective view of a battery apparatus having measuring electronics.

### PREFERRED EMBODIMENT OF THE INVENTION

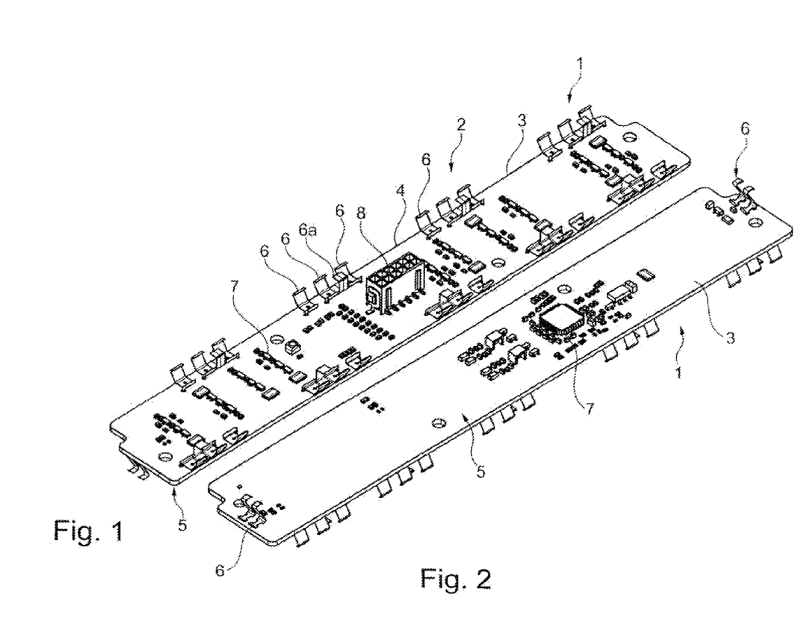

FIG. 1 shows a measuring apparatus 1 having a spring contact-making structure 2 for at least one contact element of an electrical or electronic unit to make contact with the measuring apparatus 1.

In this case, the measuring apparatus 1 in the form of an electronic assembly has a circuit board 3, resilient contact-making elements 6 being arranged on the top face 4 and also on the bottom face 5 of said circuit board. Electronic elements 7 are also arranged on the top face 4. Electrical connecting means 8, such as a plug element, are also provided in order to connect the electronic assembly to other electronic units in the vehicle or another structure. In the example in FIG. 1, the electronic assembly is in the form of a measuring apparatus 1. In other exemplary embodiments, the electronic assembly can also be another electronic unit, such as a control unit for example.

In the exemplary embodiment in FIG. 1, the resilient contact-making elements 6 are arranged in groups, wherein in each case four resilient contact-making elements 6, 6a of this kind are arranged next to one another and are electrically connected to one another. In this case, three of the contact-making elements 6 are arranged in the same direction, and a contact-making element 6a, of which the orientation is inverted, is arranged between two contact-making elements 6 of this kind.

FIG. 1 shows that the resilient contact-making elements 6, 6a are arranged in a manner distributed around the edge of the circuit board 3. In this case, the resilient contact-making elements 6, 6a are arranged in groups along the two longitudinal sides of the circuit board.

FIG. 2 shows the measuring apparatus 1 from FIG. 1 from the bottom face, wherein electronic elements 7 are further arranged on the bottom face 5. Said figure also shows that resilient contact-making elements 6 are provided. The resilient contact-making elements 6, which are arranged on the bottom face of the circuit board 3, are arranged in groups of two, wherein these groups of two are each arranged on a short transverse side of the circuit board 3.

In this case, it is advantageous when the resilient contact-making elements 6 are arranged both on the top face and also on the bottom face of the circuit board, wherein it is also feasible to configure exemplary embodiments in which the resilient contact-making elements 6 are arranged either only on the top face or only on the bottom face.

The arrangement of the resilient contact-making elements 6, 6a in groups may be advantageous when the contact elements with which contact is to be made are likewise electrically connected to one another. To this end, it is expedient when the resilient contact-making elements 6, 6a which are arranged in one group are electrically conductively connected to one another.

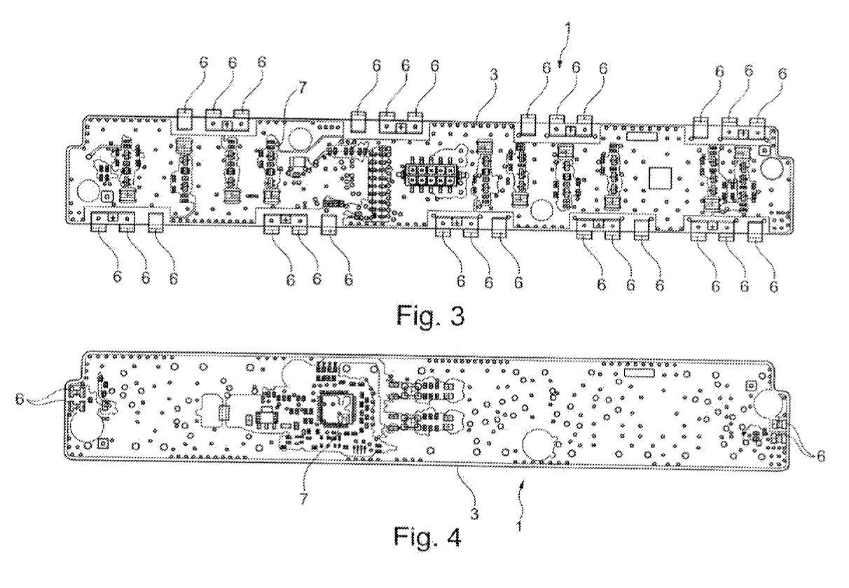

FIGS. 3 and 4 show the measuring apparatus 1 according to FIGS. 1 and 2 once again, this time in a two-dimensional illustration. Said figures show the measuring apparatus 1 having a circuit board 3 which has resilient contact elements 6 laterally at the edges. In addition, it is advantageous when the resilient contact elements are arranged in groups or in pairs. Furthermore, the electronic elements 7 both on the top face and also on the bottom face of the circuit board 3 are shown.

As shown in FIG. 2, the resilient contact-making elements 6 are formed in the shape of a Z on the bottom face in the exemplary embodiment. This means that a first region of the contact-making element, by means of which first region the resilient contact-making element is connected to the circuit board, has an approximately horizontal profile, a second region, which is situated opposite said first region, has a similarly horizontal profile, and an oblique connecting region is provided between said two horizontal regions. The resilient contact-making element 6 can be connected to the circuit board in an interlocking manner and/or in a cohesive manner, such as by soldering for example.

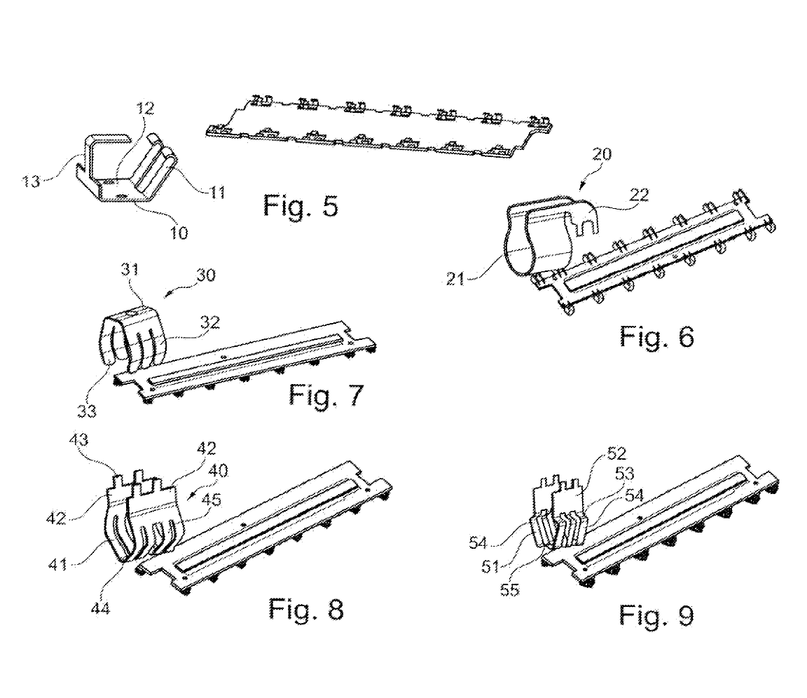

FIGS. 5 to 9 showed exemplary embodiments of resilient contact-making elements as, according to the invention, can be connected to an electronic assembly, such as to a circuit board of a measuring apparatus in particular.

FIG. 5 shows a resilient contact-making element 10 which has resilient tongues 11 and 13 and a fastening region 12, the resilient tongues 11, 13 projecting from said fastening region. The planar fastening region 12 serves, for example, for connection purposes, such as for connecting the resilient contact-making element to an electronic assembly, such as a circuit board of the measuring apparatus, in an interlocking or cohesive manner.

The tongues 11 are designed in a manner curved in the form of an arc in their upper end region and are angled, set at an angle of approximately 45° in relation to the horizontal. As viewed in the transverse direction, the tongue 13 is arranged between the two tongues 11 but projects from the opposite edge region of the base surface 12 and is angled in the shape of an L.

FIGS. 6 shows a resilient contact-making element 20 which is formed in the manner of an arc and has an approximately arcuate or omega-shaped region 21 which, at its end which is open on one side, merges with the laterally arranged retaining tongues 22 which, as viewed in the transverse direction, are arranged next to the bent region, so that the fastening region 22 can be connected to an electronic assembly or to a circuit board, and the arcuate region next to the circuit board can nevertheless project laterally.

FIG. 7 shows a resilient contact-making element 30 which has a base region 31 which is substantially flat and which serves to connect the resilient contact-making element to an electronic assembly or to a circuit board.

Three tongues 32 which are arranged next to one another project from said base region 31 from each side edge of said base region, so that a total of six tongues 32 project from the base region. In this case, the tongues 32 are bent in an approximately arcuate manner in relation to one another and have a rounded flat design at their end 33 which is situated opposite the base region 31. The resilient contact-making element 30 is typically fastened to an electronic assembly or to a circuit board and projects downward or upward from there.

The resilient contact-making element 40 in FIG. 8 has an arcuate profile 41, wherein projections 43 are provided in the end regions 42 of the arcuate profile in order to be able to connect the resilient contact-making element to the circuit board in an interlocking manner. The region of the resilient contact-making element, which region is open on one side, is utilized by the projections for fastening purposes. The arcuate profile 31 is designed with in each case four parallel tongues 44 which are arranged spaced-apart from one another and which are separated from one another by slots 45. The cross section of the resilient contact-making element is approximately of a similar shape to a bishop's cap. However, said cross section can also be of round or oval design as an alternative.

FIG. 9 shows a similar design to the exemplary embodiment in FIG. 8, wherein the arcuate region of FIG. 8 is configured as an angled, rather rectangular region 51. Starting from the fastening regions 52 which are arranged in parallel, there is an angled portion 53 toward the outside, wherein the angled portion 53 is followed by a further, web-like extension which is designated 54. A connecting region 55 is provided between two opposite web-like regions 54, said connecting region once again being angled inward at its center.

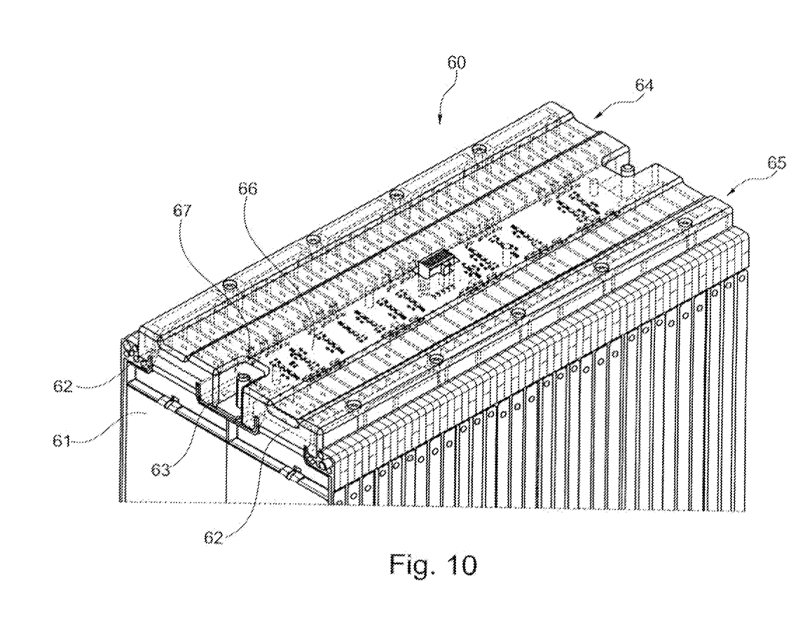

FIG. 10 shows a battery apparatus 60 having a plurality of battery cells 61 which are arranged next to one another in a row and in this case are preferably accommodated in a housing or the like.

The battery cells 61 have contact elements 62. In this case, two contact elements 62 which, as connection poles, project upward out of the battery cells 61 are preferably provided at the upper end of each battery cell 61. The contact elements 62 are preferably in the form of metallic sheet-metal strips which project out of the housing or the casing of the battery cells 61. A free space 63, which, as an elongate, flat, substantially approximately cuboidal free space, runs along the top face of the battery apparatus 60, is situated between the two contact elements 62, wherein the contact elements 62 are arranged in two rows 64, 65 likewise along the top face of the battery apparatus 60. The measuring apparatus 66 is preferably arranged in the extending free space as a receiving region 63 between the contact elements 62, wherein the resilient contact-making elements 67 of the measuring apparatus are supported against individual or against several contact elements 62. In the exemplary embodiment in FIG. 10, the resilient contact elements 67 are laterally supported against a short side of the contact element 62 of the battery cell 60.

FIG. 11 snows an alternative configuration of a battery 70 having battery cells 71 with contact elements 72, wherein the resilient contact-making element 73 is designed according to FIG. 6 and engages between two contact elements 72. The arcuate region of the contact-making element 73 is supported under prestress against the two opposite contact elements of two battery cells between which the contact-making element 73 engages. The resilient contact-making elements 73 therefore make contact with the measuring apparatus 74 by way of the contact elements 72 of the battery cells 71.

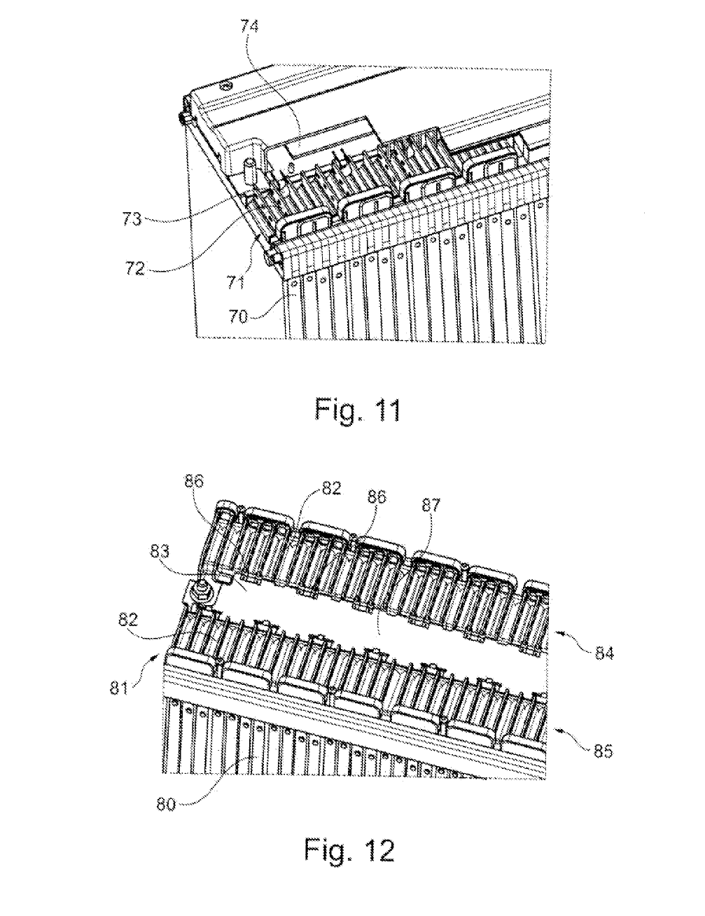

FIG. 12 shows a further exemplary embodiment of a battery apparatus 80 having battery cells 81 with contact elements 82. The measuring apparatus 83 is again situated between two rows of contact elements 84, 85 and has resilient contact-making elements 86 which are supported in a resilient manner against the short ends or side edges of the contact elements 82. As shown in FIG. 12, in each case two resilient contact-making elements 86, which make contact with two contact elements 82, are arranged in pairs. The contact-making elements 86 are arranged on the longitudinal sides of the circuit board 87 of the measuring apparatus 83 in this case, wherein the resilient contact-making elements 86 are arranged in a respectively alternating manner from one longitudinal side of the circuit board 87 to the other.

According to the invention, it is advantageous when the measuring apparatus is supported against contact elements of the battery cells by means of resilient contact-making elements. In this case, it is particularly advantageous when the measuring apparatus is resiliently supported in such a way that the measuring apparatus is mounted in a floating manner. This centers the measuring apparatus in the installation space, which is provided for said measuring apparatus, between the contact elements. In this case, it may be expedient when resilient support is provided in the four directions of the plane of the circuit board. It is also advantageous when resilient support or interlocking securing is provided in the direction perpendicular to the plane of the circuit board.

Protection against vibrations and jolting can be realized by said measuring apparatus being centered in a resilient manner and, as a result, being mounted in a floating manner.

Furthermore, the design of the spring contact-making structure has the advantage that the measuring apparatus or the circuit board can be tested in a very simple manner as a subcomponent by means of the resilient contact-making elements with corresponding contact elements of a testing apparatus making contact with the circuit board or the subcomponent. In this case, test pulses or test voltages can be applied to the circuit board and/or to the measuring apparatus in order to test the functioning of said circuit board and/or measuring apparatus. This may advantageously take place before the circuit board or the measuring apparatus is inserted into the apparatus for which they are intended, advantageously into the battery apparatus.

1. A measuring apparatus having a spring contact-making structure for at least one contact element of an electrical or electronic unit to make contact with the measuring apparatus, wherein the contact element is a protruding metallically conducting element, and the electronic assembly has at least one resilient contact-making element which is supported in an electrically conductive manner on the contact element when force is applied to it.

2. The measuring apparatus as claimed in claim 1, characterized in that the apparatus comprises a circuit board, electronic elements being arranged on at least one face or both faces of said circuit board and electrical contact being made with said electronic elements, wherein resilient contact-making elements are arranged on at least one face or both faces of the circuit board and are electrically connected.

3. The measuring apparatus as claimed in claim 2 or 3, characterized in that the apparatus comprises a circuit board on which the resilient contact-making elements are arranged in a manner distributed around the edge of the circuit board.

4. The measuring apparatus as claimed in one of the preceding claims, characterized in that the resilient contact-making elements are arranged on the long longitudinal sides on one face of the circuit board.

5. The measuring apparatus as claimed in one of the preceding claims, characterized in that the resilient contact-making elements are arranged on the short transverse sides on the opposite face of the circuit board.

6. The measuring apparatus as claimed in claims 1 to 5, characterized in that resilient contact-making elements are arranged in groups.

7. The measuring apparatus as claimed in claim 6, characterized in that the contact-making elements which are arranged in one group are electrically conductively connected to one another.

8. The measuring apparatus as claimed in at least one of the preceding claims, characterized in that the measuring apparatus is mounted in a floating and/or resilient manner by means of the resilient contact-making elements on the contact elements.

9. The measuring apparatus as claimed in at least one of the preceding claims, characterized in that a test process of the measuring apparatus or of the circuit board of the measuring apparatus can be carried out in such a way that the measuring apparatus or, respectively, the circuit board can be clamped into a testing apparatus by means of the resilient contact-making elements and signals can be supplied to the circuit board or, respectively, measuring apparatus in order to test said circuit board or measuring apparatus.

10. A spring contact-making structure, in particular for a measuring apparatus as claimed in one of the preceding claims, for at least one contact element of an electrical or electronic unit to make contact with an electronic assembly, wherein the contact element is a protruding metallically conductive element, and the electronic assembly has at least one resilient contact-making element which is supported in an electrically conductive manner on the contact element when force is applied to it.

11. The spring contact-making structure as claimed in claim 10, characterized in that the electronic assembly has a plurality of contact-making elements for making contact with a plurality of contact elements of an electrical or electronic unit or a plurality of electrical or electronic units.

12. The spring contact-making structure as claimed in claim 10 or 11, characterized in that the resilient contact-making element can be connected to the electronic assembly by way of at least one fastening region, and a part of the contact-making element, which part projects away from the fastening region, can be deformed in a resilient manner at least in one direction, and can be applied to the contact elements in such a way that resilient deformation takes place in the direction in which deformation is possible.

13. The spring contact-making structure as claimed in claim 12, characterized in that the resilient contact-making element comprises a metallic strip which can be deformed in a resilient manner in the direction perpendicular to the narrowest extent of the strip.

14. The spring contact-making structure as claimed in one of the preceding claims, characterized in that the resilient contact-making element is of C-, Z- or U-shaped design, wherein one region of the contact-making element is provided as a fastening region, it being possible for the contact-making element to be connected to the electronic assembly by means of said fastening region.

15. The spring contact-making structure as claimed in one of preceding claims 10 to 14, characterized in that the resilient contact-making element is of arcuate design, and has fastening regions in a central region or in one or in both end regions, it being possible for the contact-making element to be connected to the electronic assembly by means of said fastening region.

16. The spring contact-making structure as claimed in one of the preceding claims, characterized in that the resilient contact-making element has a plurality of resilient tongues.

17. The spring contact-making structure as claimed in one of the preceding claims, characterized in that the resilient contact-making element is applied laterally to a contact element and is supported there.

18. The spring contact-making structure as claimed in one of the preceding claims, characterized in that the resilient contact-making element engages between two contact elements and is applied to and supported on the two contact elements.

19. The spring contact-making structure as claimed in one of the preceding claims, characterized in that the electronic assembly is an electronic measuring apparatus, and the resilient contact-making elements are connected to a circuit board of the measuring device.

20. The spring contact-making structure as claimed in one of the preceding claims, characterized in that the electrical or electronic unit is a battery apparatus having a battery cell or having a plurality of battery cells.

21. A battery apparatus having at least one battery cell, preferably having a plurality of battery cells, having in each case two connection poles, which are in the form of contact elements, for each battery cell, having a measuring apparatus with resilient contact-making means, wherein the measuring apparatus makes electrical contact with at least individual contact elements by means of the resilient contact-making means.

22. The battery apparatus as claimed in claim 21, wherein the contact elements of the battery cells are arranged in two spaced-apart rows, and the measuring apparatus is arranged substantially between and/or above the two rows.

23. The battery apparatus as claimed in claim 21, wherein the measuring apparatus has a circuit board with resilient contact-making elements which are directed downward or laterally to the outside and which make contact with contact elements of the battery cells.

24. The battery apparatus as claimed in claims 21 to 23, characterized in that the measuring apparatus is arranged on the side of the contact elements of the battery apparatus and is covered by means of a cover.
